(19) United States
(12) Patent Application Publication
(10) Pub. No.: US 2025/0149301 A1
(43) Pub. Date: May 8, 2025

(54) PLASMA PROCESSING APPARATUS INCLUDING GAS DISTRIBUTION PLATE

(71) Applicant: SAMSUNG ELECTRONICS CO., LTD., Suwon-si (KR)

(72) Inventors: Chan Hoon PARK, Hwaseong-si (KR); Jung Hwan UM, Hwaseong-si (KR); Jin Young PARK, Hwaseong-si (KR); Ho Yong PARK, Hwaseong-si (KR); Jin Young BANG, Hwaseong-si (KR); Jong Woo SUN, Hwaseong-si (KR); Sang Jean JEON, Hwaseong-si (KR); Je Woo HAN, Hwaseong-si (KR)

(73) Assignee: SAMSUNG ELECTRONICS CO., LTD., Suwon-si (KR)

(21) Appl. No.: 19/009,570

(22) Filed: Jan. 3, 2025

Related U.S. Application Data
(63) Continuation of application No. 17/951,910, filed on Sep. 23, 2022.
Application No. 17/951,910 is a division of application No. 16/118,939, filed on Aug. 31, 2018, now abandoned.

(30) Foreign Application Priority Data
Mar. 29, 2018 (KR) 10-2018-0036241

(51) Int. Cl. H01J 37/32; H01L 21/67

(52) U.S. Cl. CPC H01J 37/3244; H01J 37/32715; H01L 21/67069

(57) ABSTRACT

A plasma processing apparatus may include a support configured to receive a substrate, a gas distribution plate (GDP) including a plurality of nozzles facing the support, a main splitter configured to supply a process gas, and an additional splitter configured to supply an acceleration gas or a deceleration gas. The plurality of nozzles may include a plurality of central nozzles, a plurality of outer nozzles, a plurality of middle nozzles configured to spray the process gas and the acceleration gas, a plurality of first nozzles, and a plurality of second nozzles.

### CROSS-REFERENCE TO RELATED APPLICATION

This application is a continuation of U.S. application Ser. No. 17/951,910, filed on Sep. 23, 2022, in the United States Patent and Trademark Office, which is a divisional of U.S. application Ser. No. 16/118,939, filed on Aug. 31, 2018, in the United States Patent and Trademark Office, which is based on and claims priority under 35 U.S.C. § 119 to Korean Patent Application No. 10-2018-0036241, filed on Mar. 29, 2018, in the Korean Intellectual Property Office, the disclosures of which are incorporated by reference herein in their entireties.

### FIELD

Embodiments of the present inventive concepts relate to plasma processing apparatuses including a gas distribution plate and methods of operating the same.

### BACKGROUND

A plasma processing apparatus may be used in a semiconductor manufacturing process. As the integration of semiconductor devices increase, an aspect ratio of a pattern may gradually increase. In order to form a pattern having a high aspect ratio, a plasma processing apparatus configured may be useful to provide a process gas having uniform plasma density.

### SUMMARY

Some embodiments of the inventive concepts are directed to providing plasma processing apparatuses capable of uniformly controlling plasma density.

Some embodiments of the inventive concepts are directed to providing methods of operating a plasma processing apparatus capable of uniformly controlling plasma density.

According to some embodiments, a plasma processing apparatus may include a support configured to receive a substrate, a gas distribution plate (GDP) including a plurality of nozzles facing the support, a main splitter connected to the GDP and configured to supply a process gas, and an additional splitter connected to the GDP and configured to selectively supply an acceleration gas for increasing a plasma density of the process gas or a deceleration gas for decreasing the plasma density of the process gas. The plurality of nozzles may include a plurality of central nozzles adjacent to a center of the GDP and connected to the main splitter, a plurality of outer nozzles adjacent to an outermost part of the GDP and connected to the main splitter, a plurality of middle nozzles connected to the main splitter and to the additional splitter, configured to spray the process gas and the acceleration gas, and adjacent to a middle point between the center of the GDP and the plurality of outer nozzles, a plurality of first nozzles between the plurality of central nozzles and the plurality of middle nozzles and connected to the main splitter, and a plurality of second nozzles between the plurality of middle nozzles and the plurality of outer nozzles and connected to the main splitter.

According to some embodiments, a plasma processing apparatus may include a support configured to receive a substrate, a gas distribution plate (GDP) including a plurality of nozzles facing the support, a main splitter connected to the GDP and configured to supply a process gas, and an additional splitter connected to the GDP and configured to selectively supply an acceleration gas for increasing a plasma density of the process gas or a deceleration gas for decreasing the plasma density of the process gas. The plurality of nozzles may include a plurality of central nozzles adjacent to a center of the GDP and connected to the main splitter and to the additional splitter and configured to spray the process gas and the deceleration gas, a plurality of outer nozzles adjacent to an outermost part of the GDP and connected to the main splitter, a plurality of middle nozzles adjacent to a middle point between the center of the GDP and the plurality of outer nozzles, a plurality of first nozzles between the plurality of central nozzles and the plurality of middle nozzles and connected to the main splitter, and a plurality of second nozzles between the plurality of middle nozzles and the plurality of outer nozzles and connected to the main splitter.

According to some embodiments, a GDP may include a plurality of central nozzles adjacent to a center of the gas distribution plate. The plurality of central nozzles may be configured to receive a process gas from a main splitter and configured to receive a deceleration gas for decreasing a plasma density of the process gas from an additional splitter. The GDP may include a plurality of outer nozzles adjacent an outer perimeter of the gas distribution plate and configured to receive the process gas from the main splitter. The GDP may include a plurality of middle nozzles between the plurality of central nozzles and the plurality of outer nozzles. The plurality of middle nozzles may be configured to receive the process gas from the main splitter and configured to receive an acceleration gas for increasing the plasma density of the process gas from the additional splitter. The GDP may include a plurality of first nozzles between the plurality of central nozzles and the plurality of middle nozzles and configured to receive the process gas from the main splitter, and a plurality of second nozzles between the plurality of middle nozzles and the plurality of outer nozzles and configured to receive the main gas from to the main splitter. An effective diameter of each nozzle of the plurality of middle nozzles may be greater than an effective diameter of each nozzle of the plurality of central nozzles, the plurality of first nozzles, the plurality of second nozzles, and the plurality of outer nozzles.

### BRIEF DESCRIPTION OF THE DRAWINGS

FIG. 1 is a block diagram schematically illustrating a plasma processing apparatus according to some embodiments of the inventive concepts.

FIGS. 2 to 6 are front views illustrating a surface of a gas distribution plate (GDP) used for a plasma processing apparatus according to some embodiments of the inventive concepts.

FIGS. 7 to 16 are block diagrams schematically illustrating various examples of portions of the surface of the GDP of FIG. 1 according to some embodiments of the inventive concepts.

FIG. 17 is a front view illustrating a surface of a GDP used for a plasma processing apparatus according to some embodiments of the inventive concepts.

FIGS. 18 and 19 are block diagrams schematically illustrating various examples of a portion of the surface of the GDP of FIG. 1 according to some embodiments of the inventive concepts.

FIGS. 20 and 21 are front views illustrating a surface of a GDP used for a plasma processing apparatus according to some embodiments of the inventive concepts.

### DETAILED DESCRIPTION OF EXEMPLARY EMBODIMENTS

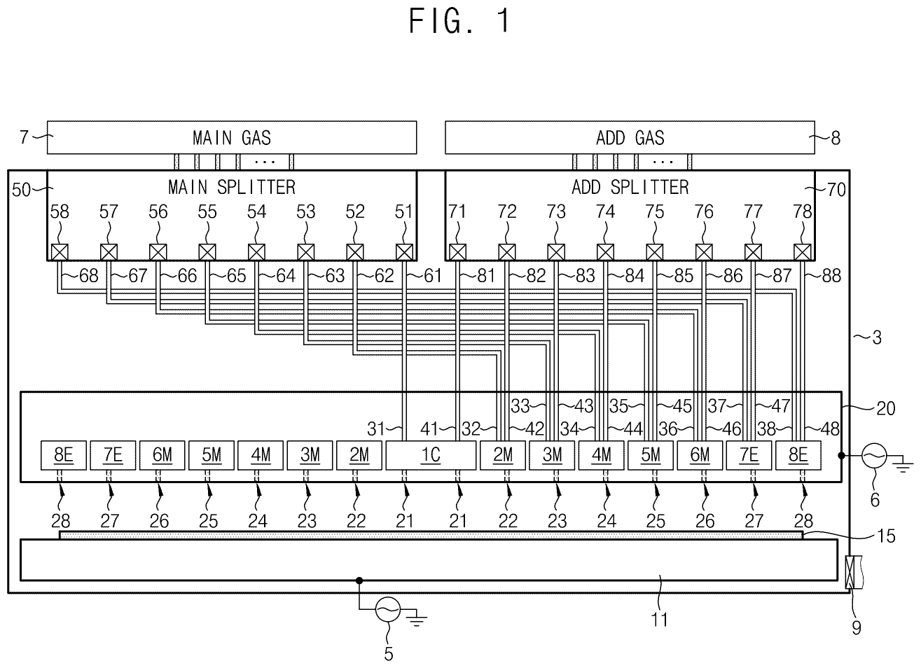

FIG. 1 is a block diagram schematically illustrating a plasma processing apparatus according to some embodiments of the inventive concepts.

Referring to FIG. 1, the plasma processing apparatus according to some embodiments may include a chamber 3, an exhaust port 9, a support 11, a gas distribution plate (GDP) 20, a main splitter 50, and an additional splitter 70. The support 11 may be connected to a first power supply 5, and the GDP 20 may be connected to a second power supply 6. The main splitter 50 may be connected to a main gas supplier 7, and the additional splitter 70 may be connected to an additional gas supplier 8. A substrate 15 may be mounted on the support 11.

The GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 33, 34, 35, 36, 37, and 38, and a plurality of additional inlet ports 41, 42, 43, 44, 45, 46, 47, and 48. The main splitter 50 may include a plurality of main flow controllers 51, 52, 53, 54, 55, 56, 57, and 58. A plurality of main pipes 61, 62, 63, 64, 65, 66, 67, and 68 may be interposed between the main splitter 50 and the GDP 20. The additional splitter 70 may include a plurality of additional flow controllers 71, 72, 73, 74, 75, 76, 77, and 78. A plurality of additional pipes 81, 82, 83, 84, 85, 86, 87, and 88 may be interposed between the additional splitter 70 and the GDP 20.

The plurality of reservoirs 1C, 2M, 3M, 4M, 5M, 6M, 7E, and 8E may include a central reservoir 1C adjacent to a center of the GDP 20, an outer reservoir 8E adjacent to an outermost portion of the GDP 20, a middle reservoir 4M between the central reservoir 1C and the outer reservoir 8E and adjacent to a central portion between the center of the GDP 20 and the outer reservoir 8E, a first reservoir 2M between the central reservoir 1C and the middle reservoir 4M, a second reservoir 5M between the middle reservoir 4M and the outer reservoir 8E, a third reservoir 3M between the first reservoir 2M and the middle reservoir 4M, a fourth reservoir 6M between the second reservoir 5M and the outer reservoir 8E, and a fifth reservoir 7E between the fourth reservoir 6M and the outer reservoir 8E.

The plurality of nozzles 21, 22, 23, 24, 25, 26, 27, and 28 may include a plurality of central nozzles 21 adjacent to the center of the GDP 20, a plurality of outer nozzles 28 adjacent to the outermost portion of the GDP 20, a plurality of middle nozzles 24 between the plurality of central nozzles 21 and the plurality of outer nozzles 28 and adjacent to a central portion between the center of the GDP 20 and the plurality of outer nozzles 28, a plurality of first nozzles 22 between the plurality of central nozzles 21 and the plurality of middle nozzles 24, a plurality of second nozzles 25 between the plurality of middle nozzles 24 and the plurality of outer nozzles 28, a plurality of third nozzles 23 between the plurality of first nozzles 22 and the plurality of middle nozzles 24, a plurality of fourth nozzles 26 between the plurality of second nozzles 25 and the plurality of outer nozzles 28, and a plurality of fifth nozzles 27 between the plurality of fourth nozzles 26 and the plurality of outer nozzles 28.

The plurality of main inlet ports 31, 32, 33, 34, 35, 36, 37, and 38 may include a first main inlet port 31, a second main inlet port 32, a third main inlet port 33, a fourth main inlet port 34, a fifth main inlet port 35, a sixth main inlet port 36, a seventh main inlet port 37, and an eighth main inlet port 38. The plurality of additional inlet ports 41, 42, 43, 44, 45, 46, 47, and 48 may include a first additional inlet port 41, a second additional inlet port 42, a third additional inlet port 43, a fourth additional inlet port 44, a fifth additional inlet port 45, a sixth additional inlet port 46, a seventh additional inlet port 47, and an eighth additional inlet port 48.

The plurality of main flow controllers 51, 52, 53, 54, 55, 56, 57, and 58 may include a first main flow controller 51, a second main flow controller 52, a third main flow controller 53, a fourth main flow controller 54, a fifth main flow controller 55, a sixth main flow controller 56, a seventh main flow controller 57, and an eighth main flow controller 58. The plurality of main pipes 61, 62, 63, 64, 65, 66, 67, and 68 may include a first main pipe 61, a second main pipe 62, a third main pipe 63, a fourth main pipe 64, a fifth main pipe 65, a sixth main pipe 66, a seventh main pipe 67, and an eighth main pipe 68.

The plurality of additional flow controllers 71, 72, 73, 74, 75, 76, 77, and 78 may include a first additional flow controller 71, a second additional flow controller 72, a third additional flow controller 73, a fourth additional flow controller 74, a fifth additional flow controller 75, a sixth additional flow controller 76, a seventh additional flow controller 77, and an eighth additional flow controller 78. The plurality of additional pipes 81, 82, 83, 84, 85, 86, 87, and 88 may include a first additional pipe 81, a second additional pipe 82, a third additional pipe 83, a fourth additional pipe 84, a fifth additional pipe 85, a sixth additional pipe 86, a seventh additional pipe 87, and an eighth additional pipe 88.

The support 11 may be in the chamber 3. The support 11 may be configured to fix the substrate 15. In other words, the support 11 may hold the substrate 15 in a fixed position. The support 11 may include an electrostatic chuck (ESC), a vacuum chuck, or a clamp chuck. The first power supply 5 may be configured to apply an electric field in the chamber 3 through the support 11. The substrate 15 may be formed of materials having various shapes, various sizes, and various kinds. Hereinafter, for convenience of description, the substrate 15 may be a semiconductor wafer having a diameter of about 300 mm. However, embodiments of the inventive concepts are not limited thereto. In some embodiments, the substrate 15 may include a plurality of stacked thin films, but detailed descriptions thereof will be omitted for brevity.

The GDP 20 may be in the chamber 3 facing the support 11. The second power supply 6 may be configured to apply an electric field in the chamber 3 through the GDP 20. In some embodiments of the inventive concepts, the second power supply 6 may serve as a ground to be connected to the GDP 20.

The main gas supplier 7 may include a gas cabinet, a gas box, a gas supply system, or a combination thereof, configured to store and supply one or more process gases. For example, the main gas supplier 7 may serve to supply various process gases, such as HF, C4F6, C4F8, CHF3, CH2F2, C5F8, O2, H2, or a combination thereof, to the main splitter 50. The main gas supplier 7 may independently, sequentially, alternately, or repetitively supply the process gases, or supply a mixture of two or more process gases. The additional gas supplier 8 may include a gas cabinet, a gas box, a gas supply system, or a combination thereof, configured to store and supply one or more additional gases. For example, the additional gas supplier 8 may serve to supply various additional gases, such as helium (He), neon (Ne), argon (Ar), krypton (Kr), xenon (Xe), or a combination thereof, to the additional splitter 70. The additional gas supplier 8 may independently, sequentially, alternately, or repetitively supply the additional gases, or supply a mixture of two or more additional gases. In some embodiments, the main gas supplier 7 and the additional gas supplier 8 may be outside the chamber 3.

The main splitter 50 and the additional splitter 70 may be adjacent to the GDP 20. The main splitter 50 may be configured to receive the process gas from the main gas supplier 7 to supply the process gas to the GDP 20. The additional splitter 70 may be configured to receive the additional gas from the additional gas supplier 8 to supply the additional gas to the GDP 20. The process gas supplied from the main splitter 50 and the additional gas supplied from the additional splitter 70 may be sprayed into the chamber 3 through the plurality of nozzles 21, 22, 23, 24, 25, 26, 27, and 28 of the GDP 20. The process gas supplied from the main splitter 50 and the additional gas supplied from the additional splitter 70 may be supplied onto a surface of the substrate 15 through the plurality of nozzles 21, 22, 23, 24, 25, 26, 27, and 28 of the GDP 20. The exhaust port 9 may be configured to discharge reaction byproducts from the chamber 3. According to some embodiments, an additional unit configured to change the process gas supplied from the main splitter 50 into a plasma may be mounted on an inner surface or an outside of the chamber 3, but a detailed description thereof may be omitted for brevity.

The plurality of reservoirs 1C, 2M, 3M, 4M, 5M, 6M, 7E, and 8E may be separated from each other. The main reservoir 1C may be on the center of the GDP 20. The main reservoir 1C may be arranged with a center of the substrate 15. The outer reservoir 8E may be arranged with an edge of the substrate 15. The plurality of nozzles 21, 22, 23, 24, 25, 26, 27, and 28 may be on a surface of the GDP 20 facing the substrate 15. The plurality of nozzles 21, 22, 23, 24, 25, 26, 27, and 28 may be connected to the plurality of reservoirs 1C, 2M, 3M, 4M, 5M, 6M, 7E, and 8E. For example, the plurality of central nozzles 21 may be connected to the central reservoir 1C, and the plurality of middle nozzles 24 may be connected to the middle reservoir 4M, and the plurality of outer nozzles 28 may be connected to the outer reservoir 8E. The plurality of outer nozzles 28 may be arranged with the edge of the substrate 15. An effective width of the GDP 20 may be determined by the plurality of outer nozzles 28.

The plurality of main inlet ports 31, 32, 33, 34, 35, 36, 37, and 38 and the plurality of additional inlet ports 41, 42, 43, 44, 45, 46, 47, and 48 may be on the other surface of the GDP 20 opposite to a surface onto which the plurality of nozzles 21, 22, 23, 24, 25, 26, 27, and 28 of the GDP 20 are disposed. The plurality of main inlet ports 31, 32, 33, 34, 35, 36, 37, and 38 may be connected to the plurality of reservoirs 1C, 2M, 3M, 4M, 5M, 6M, 7E, and 8E. For example, the first main inlet port 31 may be connected to the central reservoir 1C, and the eighth main inlet port 38 may be connected to the outer reservoir 8E. The plurality of additional inlet ports 41, 42, 43, 44, 45, 46, 47, and 48 may be connected to the plurality of reservoirs 1C, 2M, 3M, 4M, 5M, 6M, 7E, and 8E. For example, the first additional inlet port 41 may be connected to the central reservoir 1C, and the fourth additional inlet port 44 may be connected to the middle reservoir 4M, and the eighth additional inlet port 48 may be connected to the outer reservoir 8E.

The plurality of main flow controllers 51, 52, 53, 54, 55, 56, 57, and 58 and the plurality of additional flow controllers 71, 72, 73, 74, 75, 76, 77, and 78 may include mass flow controllers (MFC), solenoid operated valves, air cylinder operated valves, air motor operated valves, diaphragm operated valves, or a combination thereof. The plurality of main flow controllers 51, 52, 53, 54, 55, 56, 57, and 58 and the plurality of additional flow controllers 71, 72, 73, 74, 75, 76, 77, and 78 may be independently operated by a remote control.

The first main pipe 61 may be connected to the first main inlet port 31 and the first main flow controller 51. The second main pipe 62 may be connected to the second main inlet port 32 and the second main flow controller 52. The third main pipe 63 may be connected to the third main inlet port 33 and the third main flow controller 53. The fourth main pipe 64 may be connected to the fourth main inlet port 34 and the fourth main flow controller 54. The fifth main pipe 65 may be connected to the fifth main inlet port 35 and the fifth main flow controller 55. The sixth main pipe 66 may be connected to the sixth main inlet port 36 and the sixth main flow controller 56. The seventh main pipe 67 may be connected to the seventh main inlet port 37 and the seventh main flow controller 57. The eighth main pipe 68 may be connected to the eighth main inlet port 38 and the eighth main flow controller 58.

The first additional pipe 81 may be connected to the first additional inlet port 41 and the first additional flow controller 71. The second additional pipe 82 may be connected to the second additional inlet port 42 and the second additional flow controller 72. The third additional pipe 83 may be connected to the third additional inlet port 43 and the third additional flow controller 73. The fourth additional pipe 84 may be connected to the fourth additional inlet port 44 and the fourth additional flow controller 74. The fifth additional pipe 85 may be connected to the fifth additional inlet port 45 and the fifth additional flow controller 75. The sixth additional pipe 86 may be connected to the sixth additional inlet port 46 and the sixth additional flow controller 76. The seventh additional pipe 87 may be connected to the seventh additional inlet port 47 and the seventh additional flow controller 77. The eighth additional pipe 88 may be connected to the eighth additional inlet port 48 and the eighth additional flow controller 78.

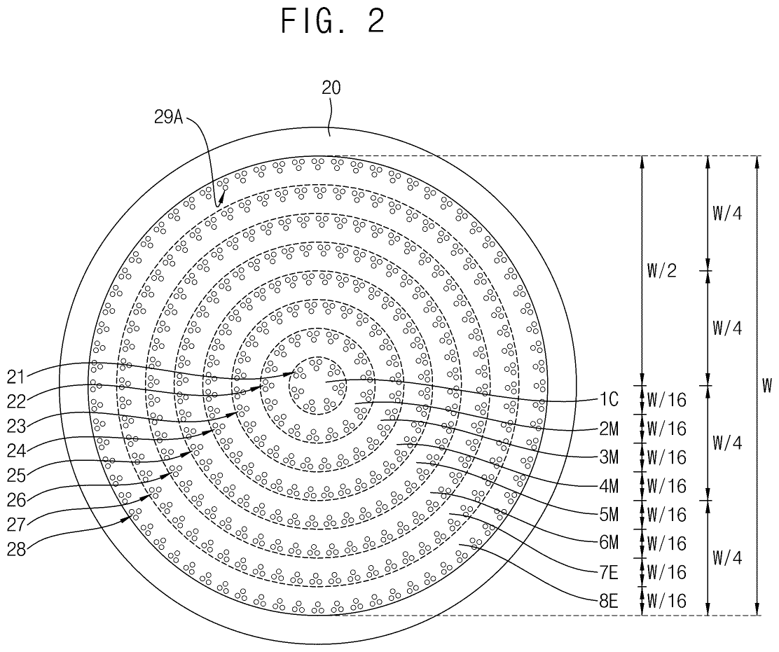

FIGS. 2 to 6 are front views illustrating a surface of a GDP used for a plasma processing apparatus according to some embodiments of the inventive concepts.

Referring to FIG. 2, in some embodiments, each of a plurality of nozzles 21, 22, 23, 24, 25, 26, 27, and 28 may be arranged along an edge of a corresponding reservoir among a plurality of reservoirs 1C, 2M, 3M, 4M, 5M, 6M, 7E, and 8E. A plurality of central nozzles 21 may be adjacent to a center of a GDP 20, and may be along an edge of a central reservoir 1C in a ring shape. A plurality of first nozzles 22 may surround outer sides of the plurality of central nozzles 21 and may be along an edge of a first reservoir 2M in a ring shape. A plurality of third nozzles 23 may surround outer sides of the plurality of first nozzles 22 and may be along a third reservoir 3M in a ring shape. A plurality of middle nozzles 24 may surround outer sides of the plurality of third nozzles 23 and may be along an edge of a middle reservoir 4M in a ring shape. A plurality of second nozzles 25 may surround outer sides of the plurality of middle nozzles 24 and may be along an edge of a second reservoir 5M in a ring shape. A plurality of fourth nozzles 26 may surround outer sides of the plurality of second nozzles 25 and may be along an edge of a fourth reservoir 6M in a ring shape. A plurality of fifth nozzles 27 may surround outer sides of the plurality of fourth nozzles 26 and may be along an edge of a fifth reservoir 7E in a ring shape. A plurality of outer nozzles 28 may surround outer sides of the plurality of fifth nozzles 27 and may be along an edge of an outer reservoir 8E in a ring shape. The plurality of nozzles 21, 22, 23, 24, 25, 26, 27, and 28 may be arranged in concentric circles.

The central reservoir 1C may be on the center of the GDP 20. The outer reservoir 8E may be on an outermost part of the plurality of reservoirs 1C, 2M, 3M, 4M, 5M, 6M, 7E, and 8E. The outer reservoir 8E may be adjacent to the outermost part of the GDP 20. The central reservoir 1C may have a disc shape. Each of the first reservoir 2M, the third reservoir 3M, the middle reservoir 4M, the second reservoir 5M, the fourth reservoir 6M, the fifth reservoir 7E, and the outer reservoir 8E may have an annular ring shape or a donut shape. The plurality of reservoirs 1C, 2M, 3M, 4M, 5M, 6M, 7E, and 8E may be arranged in concentric circles.

Each of the first reservoir 2M, the third reservoir 3M, the middle reservoir 4M, the second reservoir 5M, the fourth reservoir 6M, the fifth reservoir 7E, and the outer reservoir 8E may have substantially the same lateral width. A radius of the central reservoir 1C may be substantially the same as the lateral width of each of the first reservoir 2M, the third reservoir 3M, the middle reservoir 4M, the second reservoir 5M, the fourth reservoir 6M, the fifth reservoir 7E, and the outer reservoir 8E.

Each of the plurality of nozzles 21, 22, 23, 24, 25, 26, 27, and 28 may include one or a plurality of first sub-nozzles 29A. For example, each of the plurality of nozzles 21, 22, 23, 24, 25, 26, 27, and 28 may include three first sub-nozzles 29A arranged in a triangular shape. The first sub-nozzle 29A may have a diameter less than or equal to, for example, about 5 mm. It has been observed that a diameter of the first sub-nozzle 29A that is greater than about 5 mm may produce an unpredictable, uncontrollable, and rapid chemical reaction. However, an effective diameter of each of the plurality of nozzles 21, 22, 23, 24, 25, 26, 27, and 28 having three first sub-nozzles 29A may be equal to the diameter of a circle having an area that is three times an area of each of the individual first sub-nozzles 29A. Accordingly, the effective diameter of ones of the plurality of nozzles 21, 22, 23, 24, 25, 26, 27, and 28 may be greater than about 5 mm even though each of the respective first sub-nozzles 29A may have a diameter less than or equal to about 5 mm.

An effective width W of the GDP 20 may be determined by the plurality of outer nozzles 28. The effective width W of the GDP 20 may be similar to or substantially the same as a diameter of a circle formed by the outer reservoir 8E. The plurality of central nozzles 21 may be in a position spaced apart from the center of the GDP 20 by, for example, about one sixteenth (W/16) of the effective width W. The plurality of first nozzles 22 and the plurality of outer nozzles 28 may be on an outer side of the plurality of central nozzles 21 sequentially spaced apart from each other by about one sixteenth (W/16) of the effective width W. The plurality of middle nozzles 24 may be adjacent to a position spaced apart from the center of the GDP 20 by about one fourth (W/4) of the effective width W.

In some embodiments, one side of the GDP 20 may be referred to as a shower head. The first sub-nozzle 29A may be referred to as a sub-nozzle.

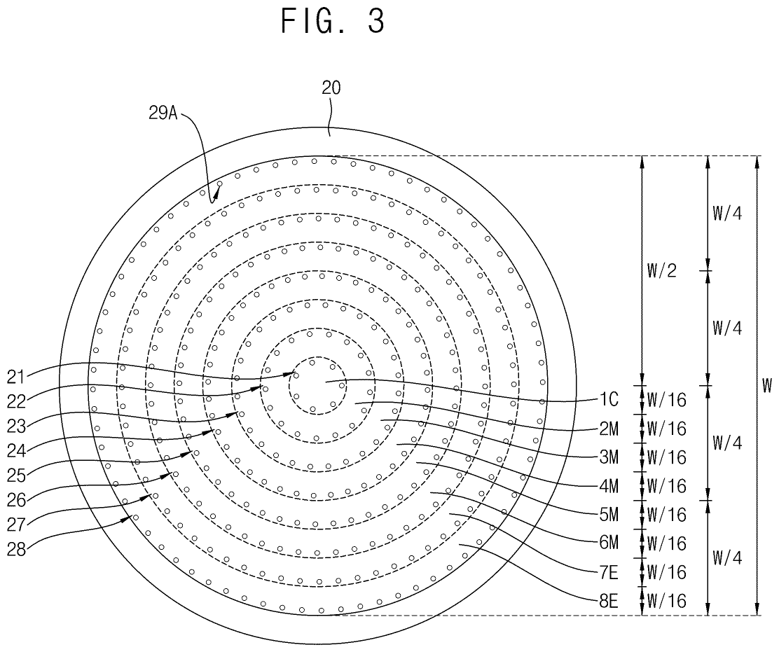

Referring to FIG. 3, in some embodiments each of the plurality of nozzles 21, 22, 23, 24, 25, 26, 27, and 28 may include one first sub-nozzle 29A.

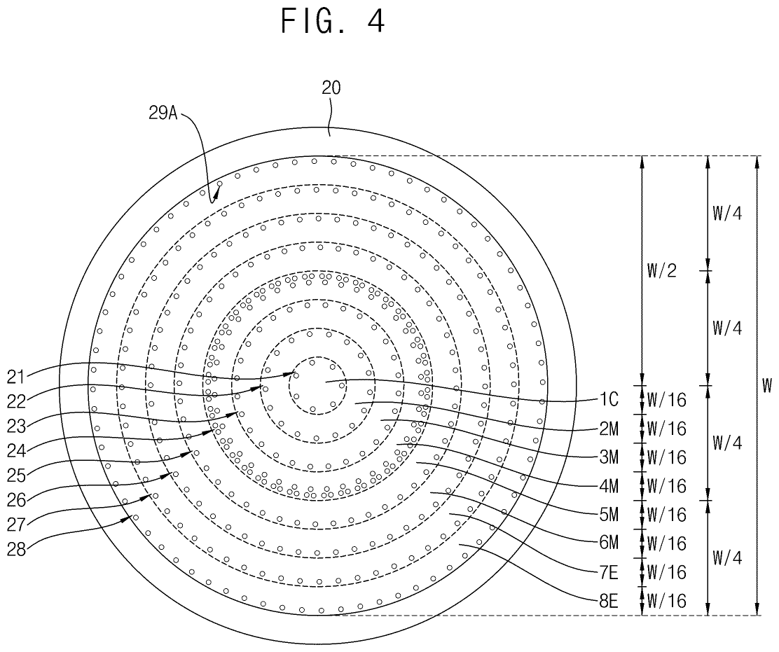

Referring to FIG. 4, in some embodiments, the number of first sub-nozzles 29A included in each of the plurality of middle nozzles 24 may be greater than the number of first sub-nozzles 29A included in each of the plurality of central nozzles 21, the plurality of first nozzles 22, the plurality of third nozzles 23, the plurality of second nozzles 25, the plurality of fourth nozzles 26, the plurality of fifth nozzles 27, and/or the plurality of outer nozzles 28. In some embodiments, each of the middle nozzles 24 may include three first sub-nozzles 29A arranged in a triangular shape. Each of the plurality of central nozzles 21, the plurality of first nozzles 22, the plurality of third nozzles 23, the plurality of second nozzles 25, the plurality of fourth nozzles 26, the plurality of fifth nozzles 27, and/or the plurality of outer nozzles 28 may include one first sub-nozzle 29A.

It has been observed that, in some embodiments, when each of the plurality of middle nozzles 24 includes three first sub-nozzles 29A, and each of the plurality of central nozzles 21, the plurality of first nozzles 22, the plurality of third nozzles 23, the plurality of second nozzles 25, the plurality of fourth nozzles 26, the plurality of fifth nozzles 27, and the plurality of outer nozzles 28 includes one first sub-nozzle 29A, plasma density of a process gas may be efficiently controlled to be uniform.

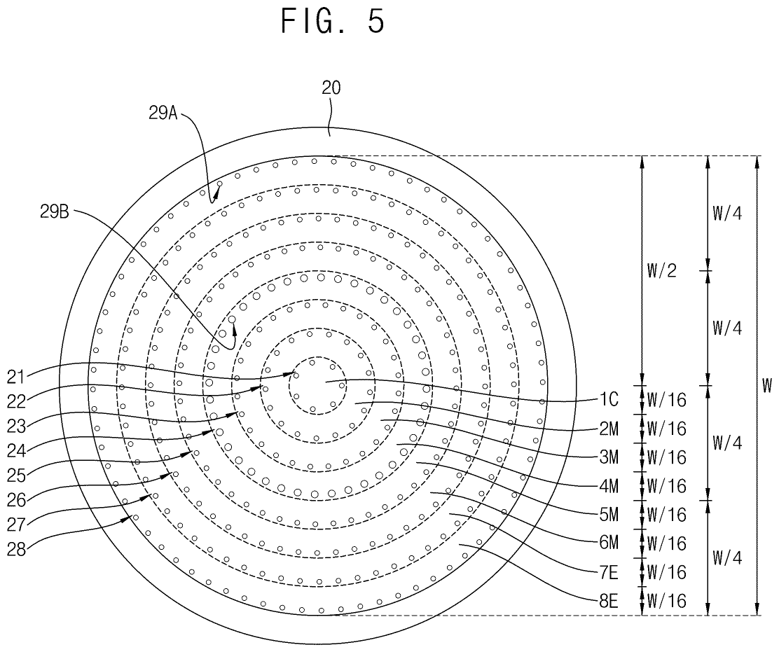

Referring to FIG. 5, in some embodiments, each of the plurality of central nozzles 21, the plurality of first nozzles 22, the plurality of third nozzles 23, the plurality of second nozzles 25, the plurality of fourth nozzles 26, the plurality of fifth nozzles 27, and the plurality of outer nozzles 28 may include one first sub-nozzle 29A. Each of the middle nozzles 24 may include one second sub-nozzle 29B. A diameter of the second sub-nozzle 29B may be greater than a diameter of the first sub-nozzle 29A. A ratio of a diameter of the second sub-nozzle 29B to a diameter of the first sub-nozzle 29A may be about 5:3. The second sub-nozzle 29B may have a diameter less than or equal to about 5 mm. The first sub-nozzle 29A may have a diameter less than or equal to about 3 mm. Accordingly, an effective diameter of each of the plurality of nozzles 21, 22, 23, 24, 25, 26, 27, and 28 having one first sub-nozzle 29A or one second sub-nozzle 29B may be equal to the diameter of the respective one of the first sub-nozzle 29A or second sub-nozzle 29B.

It has been observed that, in some embodiments, when the ratio of a diameter of the second sub-nozzle 29B to a diameter of the first sub-nozzle 29A is about 5:3, plasma density of a process gas may be efficiently controlled to be uniform.

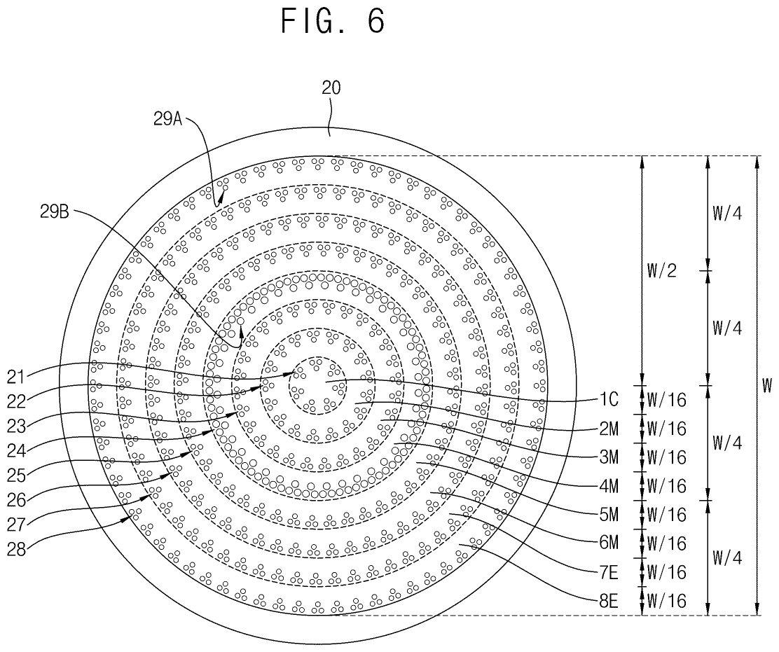

Referring to FIG. 6, in some embodiments, each of the plurality of central nozzles 21, the plurality of first nozzles 22, the plurality of third nozzles 23, the plurality of second nozzles 25, the plurality of fourth nozzles 26, the plurality of fifth nozzles 27, and the plurality of outer nozzles 28 may include three first sub-nozzles 29A arranged in a triangular shape. Each of the middle nozzles 24 may include three second sub-nozzles 29B arranged in a triangular shape. A ratio of a diameter of the second sub-nozzle 29B to a diameter of the first sub-nozzle 29A may be about 5:3. The second sub-nozzle 29B may have a diameter less than or equal to about 5 mm. The first sub-nozzle 29A may have a diameter less than or equal to about 3 mm.

It has been observed that, in some embodiments, when the ratio of a diameter of the second sub-nozzle 29B to a diameter of the first sub-nozzle 29A is about 5:3, plasma density of a process gas may be efficiently controlled to be uniform.

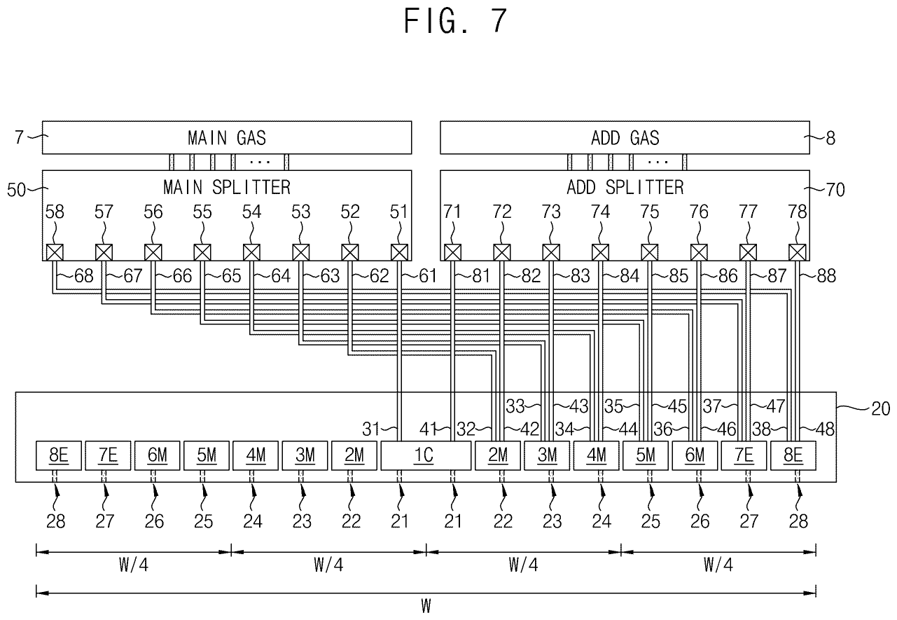

FIGS. 7 to 16 are block diagrams schematically illustrating various examples of portions of the surface of the GDP of FIG. 1 according to some embodiments of the inventive concepts.

Referring to FIG. 7, in some embodiments, a plurality of main inlet ports 31, 32, 33, 34, 35, 36, 37, and 38 may include a first main inlet port 31, a second main inlet port 32, a third main inlet port 33, a fourth main inlet port 34, a fifth main inlet port 35, a sixth main inlet port 36, a seventh main inlet port 37, and an eighth main inlet port 38. A plurality of additional inlet ports 41, 42, 43, 44, 45, 46, 47, and 48 may include a first additional inlet port 41, a second additional inlet port 42, a third additional inlet port 43, a fourth additional inlet port 44, a fifth additional inlet port 45, a sixth additional inlet port 46, a seventh additional inlet port 47, and an eighth additional inlet port 48. A plurality of main flow controllers 51, 52, 53, 54, 55, 56, 57, and 58 may include a first main flow controller 51, a second main flow controller 52, a third main flow controller 53, a fourth main flow controller 54, a fifth main flow controller 55, a sixth main flow controller 56, a seventh main flow controller 57, and an eighth main flow controller 58. A plurality of additional flow controllers 71, 72, 73, 74, 75, 76, 77, and 78 may include a first additional flow controller 71, a second additional flow controller 72, a third additional flow controller 73, a fourth additional flow controller 74, a fifth additional flow controller 75, a sixth additional flow controller 76, a seventh additional flow controller 77, and an eighth additional flow controller 78.

Referring again to FIGS. 1 to 7, the effective width W of the GDP 20 may be determined by the plurality of outer nozzles 28. The effective width W of the GDP 20 may be similar to or substantially the same as a diameter of a circle formed by the outer reservoir 8E. The effective width W of the GDP 20 may be greater than or equal to a lateral width of the substrate 15. For example, the lateral width of the substrate 15 may be about 300 mm, and the effective width W of the GDP 20 may be about 320 mm.

A process gas supplied from the main gas supplier 7 may pass through the main splitter 50 and the GDP 20, and may be supplied into the chamber 3 toward the substrate 15. The plurality of main flow controllers 51, 52, 53, 54, 55, 56, 57, and 58 may be configured to independently control flows of process gases supplied to the plurality of reservoirs 1C, 2M, 3M, 4M, 5M, 6M, 7E, and 8E through the plurality of main pipes 61, 62, 63, 64, 65, 66, 67, and 68 and the plurality of main inlet ports 31, 32, 33, 34, 35, 36, 37, and 38. The process gas supplied from the main splitter 50 may be sprayed into the chamber through the plurality of nozzles 21, 22, 23, 24, 25, 26, 27, and 28. The process gas supplied into the chamber 3 may become plasma and may be supplied onto a surface of the substrate 15. The plurality of main flow controllers 51, 52, 53, 54, 55, 56, 57, and 58 may be independently controlled so that the process gas having a uniform density in the plasma state may be controlled and supplied to the entire surface of the substrate 15.

An additional gas supplied from the additional gas supplier 8 may be supplied into the chamber 3 toward the substrate 15 through the additional splitter 70 and the GDP 20. The plurality of additional flow controllers 71, 72, 73, 74, 75, 76, 77, and 78 may be configured to independently control flows of additional gases supplied to the plurality of reservoirs 1C, 2M, 3M, 4M, 5M, 6M, 7E, and 8E through the plurality of additional pipes 81, 82, 83, 84, 85, 86, 87, and 88 and the plurality of additional inlet ports 41, 42, 43, 44, 45, 46, 47, and 48.

The additional gas supplied from the additional splitter 70 toward the plurality of reservoirs 1C, 2M, 3M, 4M, 5M, 6M, 7E, and 8E and sprayed through the plurality of nozzles 21, 22, 23, 24, 25, 26, 27, and 28 may include, for example, an acceleration gas for increasing a plasma density of the process gas or a deceleration gas for decreasing the plasma density of the process gas. The additional gas supplied to the plurality of reservoirs 1C, 2M, 3M, 4M, 5M, 6M, 7E, and 8E may accelerate or decelerate plasma formation of the process gas supplied into the chamber 3. The plurality of main flow controllers 51, 52, 53, 54, 55, 56, 57, and 58 and the plurality of additional flow controllers 71, 72, 73, 74, 75, 76, 77, and 78 may be independently controlled so that the process gas having a uniform density in the plasma state may be supplied onto the entire surface of the substrate 15.

The additional gas may include the deceleration gas for decreasing the plasma density of the process gas. When ionization energy of the additional gas supplied to the plurality of reservoirs 1C, 2M, 3M, 4M, 5M, 6M, 7E, and 8E is relatively high, the plasma formation of the process gas sprayed through the plurality of nozzles 21, 22, 23, 24, 25, 26, 27, and 28 and supplied into the chamber 3 may be decelerated. For example, a deceleration gas having ionization energy greater than or equal to about 20 eV may be selectively supplied to the plurality of reservoirs 1C, 2M, 3M, 4M, 5M, 6M, 7E, and 8E so that the plasma density of the process gas supplied into the chamber 3 may be locally decreased. According to some embodiments, a deceleration gas such as helium (He), neon (Ne), or a combination thereof may be selectively supplied to the plurality of reservoirs 1C, 2M, 3M, 4M, 5M, 6M, 7E, and 8E so that the plasma density of the process gas supplied into the chamber 3 may be locally decreased.

The additional gas may include the acceleration gas for increasing the plasma density of the process gas. When ionization energy of the additional gas supplied to the plurality of reservoirs 1C, 2M, 3M, 4M, 5M, 6M, 7E, and 8E is relatively low, the plasma formation of the process gas sprayed through the plurality of nozzles 21, 22, 23, 24, 25, 26, 27, and 28 and supplied into the chamber 3 may be accelerated. For example, an acceleration gas having ionization energy less than about 20 eV may be selectively supplied to the plurality of reservoirs 1C, 2M, 3M, 4M, 5M, 6M, 7E, and 8E so that the plasma density of the process gas supplied into the chamber 3 may be locally increased. According to some embodiments, an additional gas such as argon (Ar), krypton (Kr), xenon (Xe), or a combination thereof may be selectively supplied to the plurality of reservoirs 1C, 2M, 3M, 4M, 5M, 6M, 7E, and 8E so that the plasma density of the process gas supplied into the chamber 3 may be locally increased.

It has been observed that, in some embodiments, a plasma density of the process gas supplied into the chamber 3 at a middle point between the center of the GDP 20 and the edge thereof may be relatively low. The edge of the GDP 20 may be determined by the plurality of outer nozzles 28 on the outermost part among the plurality of nozzles 21, 22, 23, 24, 25, 26, 27, and 28. The effective width W of the GDP 20 may be determined by the plurality of outer nozzles 28. The middle point of a radius of the GDP 20 may be located at a position spaced apart from the center thereof by about one fourth (W/4) of the effective width W. The plurality of middle nozzles 24 may be adjacent to a point spaced apart from the center of the GDP 20 by about one fourth (W/4) of the effective width W. The middle nozzle 24 may be connected to the middle reservoir 4M.

The acceleration gas having relatively low ionization energy may be supplied to the middle reservoir 4M through the fourth additional pipe 84 and the fourth additional inlet port 44 using the fourth additional flow controller 74 so that the plasma density of the process gas may be locally increased. The acceleration gas having the ionization energy less than 20 eV may be supplied to the middle reservoir 4M using the fourth additional flow controller 74 so that the plasma density of the process gas may be locally increased. The additional gas, such as argon (Ar), krypton (Kr), xenon (Xe), or a combination thereof, may be supplied to the middle reservoir 4M using the fourth additional flow controller 74 so that the plasma density of the process gas may be locally increased. The additional gas, such as Ar, Kr, Xe, or a combination thereof, may be controlled and supplied to the middle reservoir 4M using the fourth additional flow controller 74 so that the process gas having a uniform density in the plasma state may be supplied onto the entire surface of the substrate 15.

It has been observed that, in some embodiments, a plasma density of the process gas supplied into the chamber 3 in a central region of the GDP 20 may be relatively high. The plurality of central nozzles 21 may be adjacent to the center of the GDP 20. The plurality of central nozzles 21 may be connected to the central reservoir 1C. The deceleration gas having relatively high ionization energy may be supplied to the central reservoir 1C through the first additional pipe 81 and the first additional inlet port 41 using the first additional flow controller 71 so that the plasma density of the process gas may be locally decreased. The deceleration gas having the ionization energy greater than or equal to about 20 eV may be supplied to the central reservoir 1C using the first additional flow controller 71 so that the plasma density of the process gas may be locally decreased. The deceleration gas, such as He, Ne, or a combination thereof, may be supplied to the central reservoir 1C using the first additional flow controller 71 so that the plasma density of the process gas may be locally decreased. The additional gas, such as He, Ne, or a combination thereof, may be supplied to the central reservoir 1C using the first additional flow controller 71 so that the process gas having a uniform density in the plasma state may be supplied onto the entire surface of the substrate 15.

In some embodiments, the deceleration gas having relatively high ionization energy may be supplied to the central reservoir 1C using the first additional flow controller 71, and the acceleration gas having relatively low ionization energy may be supplied to the middle reservoir 4M using the fourth additional flow controller 74, and thus, the process gas having a uniform density in the plasma state may be supplied onto the entire surface of the substrate 15. The deceleration gas having the ionization energy greater than or equal to about 20 eV may be supplied to the central reservoir 1C using the first additional flow controller 71, and the acceleration gas having the ionization energy less than about 20 eV may be supplied to the middle reservoir 4M using the fourth additional flow controller 74, and thus, the process gas having a uniform density in the plasma state may be supplied onto the entire surface of the substrate 15. The deceleration gas, such as He, Ne, or a combination thereof, may be supplied to the central reservoir 1C using the first additional flow controller 71, and the acceleration gas, such as Ar, Kr, Xe, or a combination thereof, may be supplied to the middle reservoir 4M using the fourth additional flow controller 74, and thus, the process gas having a uniform density in the plasma state may be supplied onto the entire surface of the substrate 15.

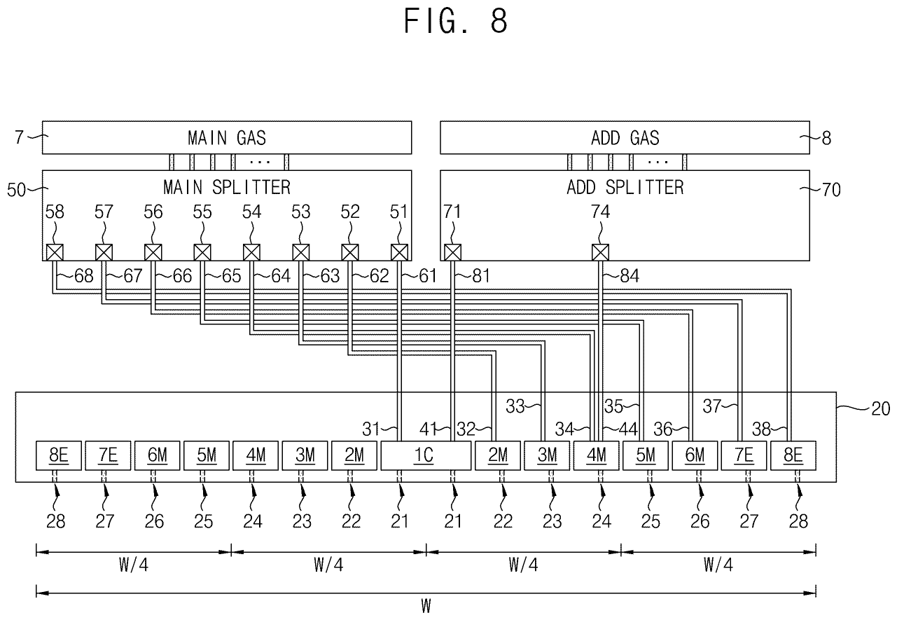

Referring to FIG. 8, in some embodiments, the GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 33, 34, 35, 36, 37, and 38, and a plurality of additional inlet ports 41 and 44. The plurality of additional inlet ports 41 and 44 may include a first additional inlet port 41 and a fourth additional inlet port 44.

The additional splitter 70 may include a plurality of additional flow controllers 71 and 74. The plurality of additional flow controllers 71 and 74 may include a first additional flow controller 71 and a fourth additional flow controller 74. A plurality of additional pipes 81 and 84 may be connected between the additional splitter 70 and the GDP 20. The plurality of additional pipes 81 and 84 may include a first additional pipe 81 and a fourth additional pipe 84. In some embodiments, the first additional pipe 81 may be referred to as an additional pipe.

The process gas supplied from the main splitter 50 to the plurality of reservoirs 1C, 2M, 3M, 4M, 5M, 6M, 7E, and 8E may be sprayed through the plurality of nozzles 21, 22, 23, 24, 25, 26, 27, and 28. The additional splitter 70 may be configured to selectively supply an acceleration gas for increasing a plasma density of the process gas and a deceleration gas for decreasing the plasma density of the process gas to the central reservoir 1C and the middle reservoir 4M. For example, the plurality of central nozzles 21 may spray the process gas and the deceleration gas. The plurality of middle nozzles 24 may spray the process gas and the acceleration gas.

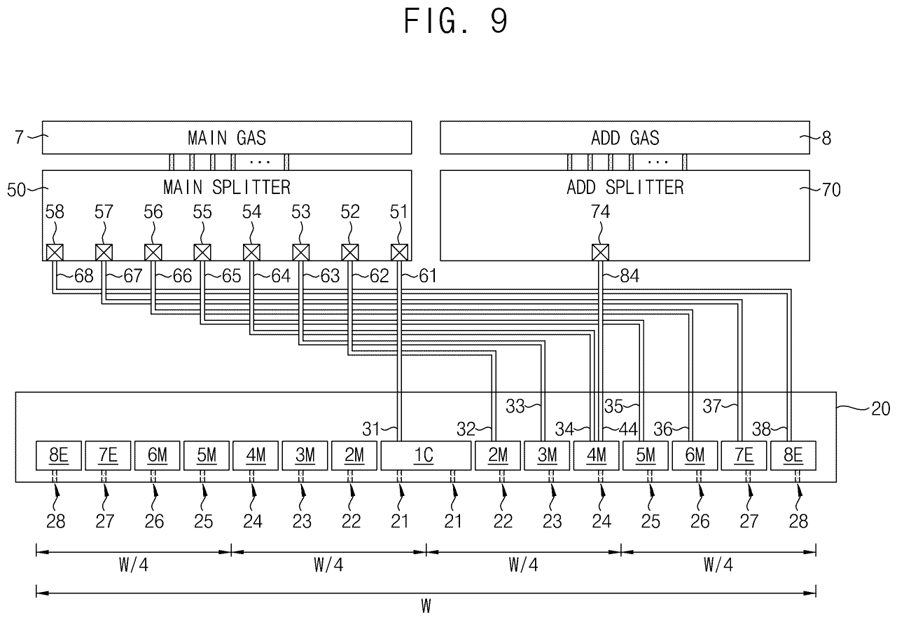

Referring to FIG. 9, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 33, 34, 35, 36, 37, and 38, and a fourth additional inlet port 44. The additional splitter 70 may include a fourth additional flow controller 74. A fourth additional pipe 84 may be interposed between the fourth additional flow controller 74 and the fourth additional inlet port 44. The plurality of middle nozzles 24 may spray a process gas and an acceleration gas for a increasing plasma density of the process gas.

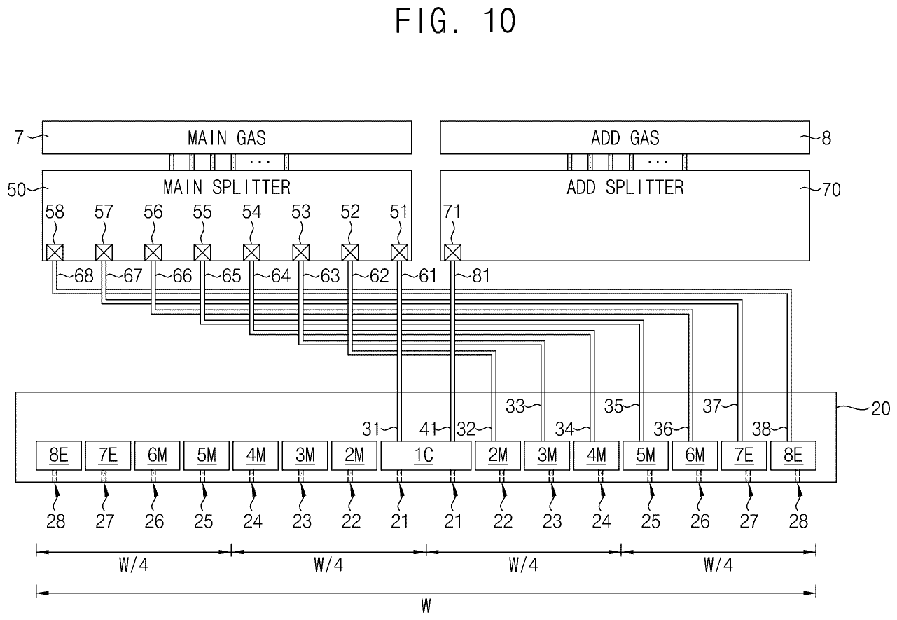

Referring to FIG. 10, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 33, 34, 35, 36, 37, and 38, and a first additional inlet port 41. The additional splitter 70 may include a first additional flow controller 71. A first additional pipe 81 may be interposed between the first additional flow controller 71 and the first additional inlet port 41. The plurality of central nozzles 21 may spray a process gas and a deceleration gas for decreasing a plasma density of the process gas.

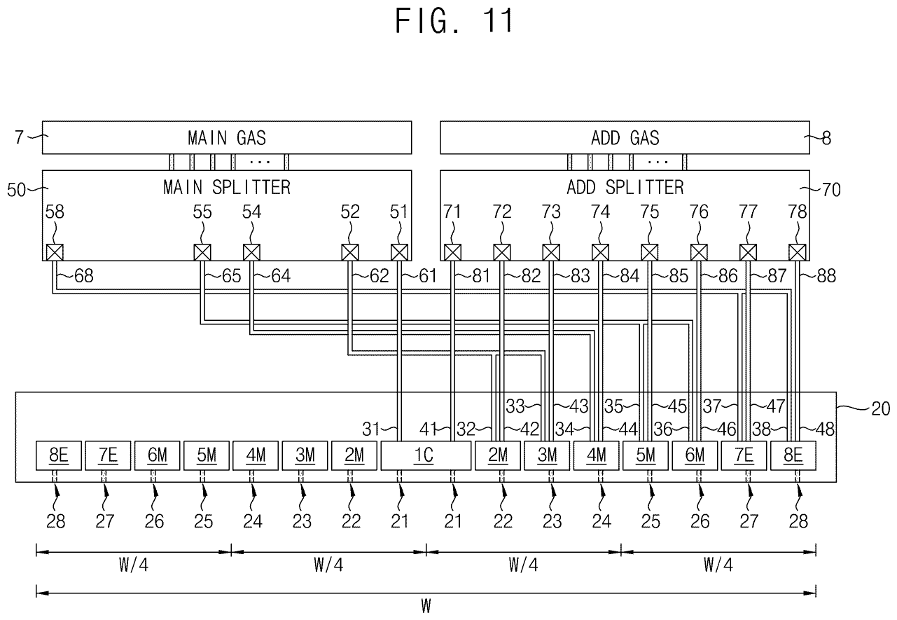

Referring to FIG. 11, in some embodiments, a main splitter 50 may include a plurality of main flow controllers 51, 52, 54, 55, and 58. The plurality of main flow controllers 51, 52, 54, 55, and 58 may include a first main flow controller 51, a second main flow controller 52, a fourth main flow controller 54, a fifth main flow controller 55, and an eighth main flow controller 58. A plurality of main pipes 61, 62, 64, 65, and 68 may be interposed between the main splitter 50 and the GDP 20. The plurality of main pipes 61, 62, 64, 65, and 68 may include a first main pipe 61, a second main pipe 62, a fourth main pipe 64, a fifth main pipe 65, and an eighth main pipe 68. The second main pipe 62 may be connected to the second main inlet port 32 and the third main inlet port 33. The fifth main pipe 65 may be connected to the fifth main inlet port 35 and the sixth main inlet port 36. The eighth main pipe 68 may be connected to the seventh main inlet port 37 and the eighth main inlet port 38.

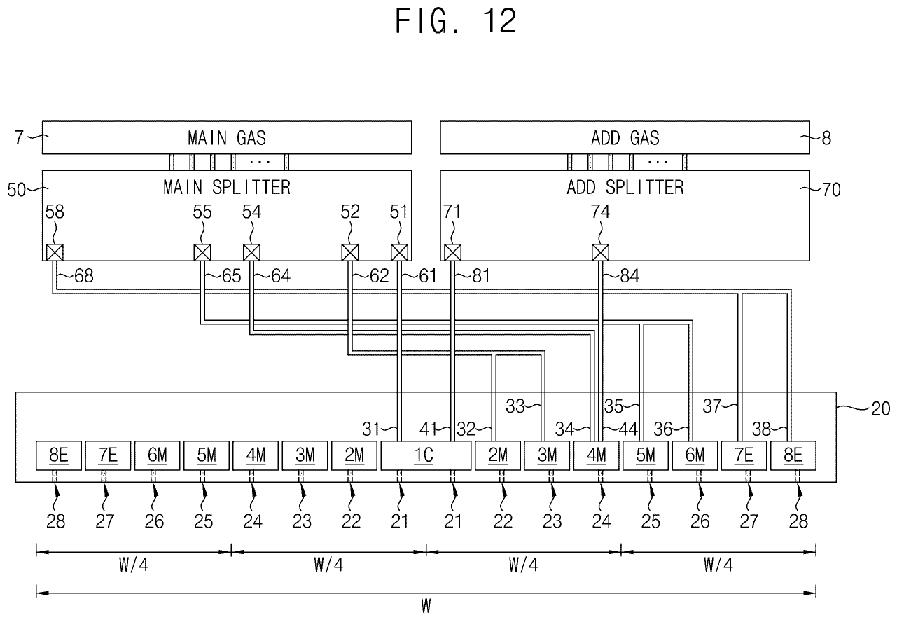

Referring to FIG. 12, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 33, 34, 35, 36, 37, and 38, and a plurality of additional inlet ports 41 and 44. The plurality of additional inlet ports 41 and 44 may include a first additional inlet port 41 and a fourth additional inlet port 44.

The main splitter 50 may include a plurality of main flow controllers 51, 52, 54, 55, and 58. The plurality of main pipes 61, 62, 64, 65, and 68 may be interposed between the main splitter 50 and a GDP 20. The additional splitter 70 may include a plurality of additional flow controllers 71 and 74. The plurality of additional flow controllers 71 and 74 may include a first additional flow controller 71 and a fourth additional flow controller 74. A plurality of additional pipes 81 and 84 may be interposed between the additional splitter 70 and the GDP 20. The plurality of additional pipes 81 and 84 may include a first additional pipe 81 and a fourth additional pipe 84.

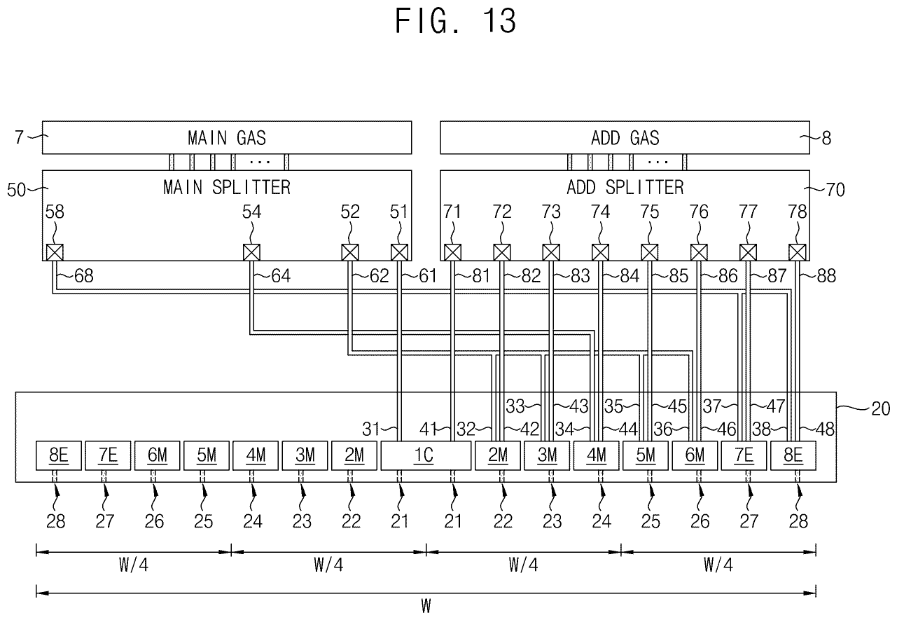

Referring to FIG. 13, in some embodiments, a main splitter 50 may include a plurality of main flow controllers 51, 52, 54, and 58. The plurality of main flow controllers 51, 52, 54, and 58 may include a first main flow controller 51, a second main flow controller 52, a fourth main flow controller 54, and an eighth main flow controller 58. A plurality of main pipes 61, 62, 64, and 68 may be interposed between the main splitter 50 and the GDP 20. The plurality of main pipes 61, 62, 64, and 68 may include a first main pipe 61, a second main pipe 62, a fourth main pipe 64, and an eighth main pipe 68. The second main pipe 62 may be connected to a second main inlet port 32, a third main inlet port 33, a fifth main inlet port 35, and a sixth main inlet port 36. The eighth main pipe 68 may be connected to a seventh main inlet port 37 and an eighth main inlet port 38.

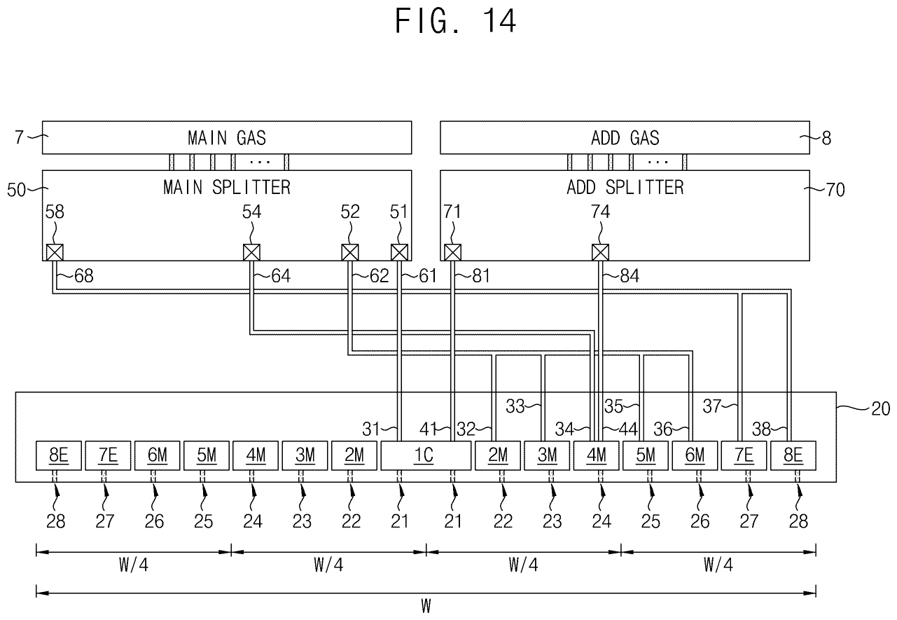

Referring to FIG. 14, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 33, 34, 35, 36, 37, and 38, and a plurality of additional inlet ports 41 and 44. The plurality of additional inlet ports 41 and 44 may include a first additional inlet port 41 and a fourth additional inlet port 44.

A main splitter 50 may include a plurality of main flow controllers 51, 52, 54, and 58. A plurality of main pipes 61, 62, 64, and 68 may be interposed between the main splitter 50 and the GDP 20. The additional splitter 70 may include a plurality of additional flow controllers 71 and 74. The plurality of additional flow controllers 71 and 74 may include a first additional flow controller 71 and a fourth additional flow controller 74. A plurality of additional pipes 81 and 84 may be interposed between the additional splitter 70 and the GDP 20. The plurality of additional pipes 81 and 84 may include a first additional pipe 81 and a fourth additional pipe 84.

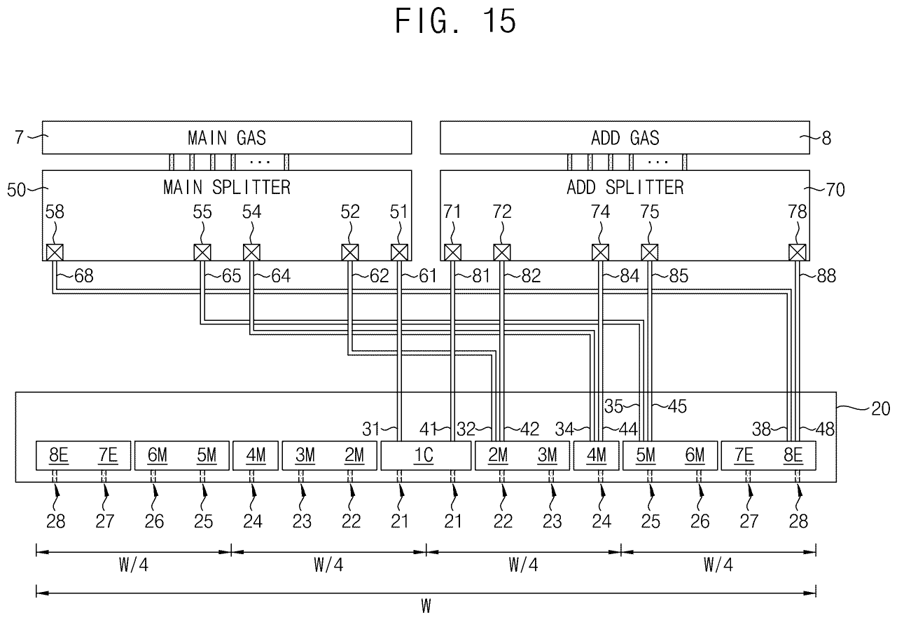

Referring to FIG. 15, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 34, 35, and 38, and a plurality of additional inlet ports 41, 42, 44, 45, and 48. A third reservoir 3M may be connected to a first reservoir 2M. A fourth reservoir 6M may be connected to a second reservoir 5M. A fifth reservoir 7E may be connected to an outer reservoir 8E. The plurality of main inlet ports 31, 32, 34, 35, and 38 may include a first main inlet port 31, a second main inlet port 32, a fourth main inlet port 34, a fifth main inlet port 35, and an eighth main inlet port 38. The plurality of additional inlet ports 41, 42, 44, 45, and 48 may include a first additional inlet port 41, a second additional inlet port 42, a fourth additional inlet port 44, a fifth additional inlet port 45, and an eighth additional inlet port 48.

A main splitter 50 may include a plurality of main flow controllers 51, 52, 54, 55, and 58. The plurality of main flow controllers 51, 52, 54, 55, and 58 may be interposed between the main splitter 50 and the GDP 20. An additional splitter 70 may include a plurality of additional flow controllers 71, 72, 74, 75, and 78. The plurality of additional flow controllers 71, 72, 74, 75, and 78 may include a first additional flow controller 71, a second additional flow controller 72, a fourth additional flow controller 74, a fifth additional flow controller 75, and an eighth additional flow controller 78. A plurality of additional pipes 81, 82, 84, 85, and 88 may be interposed between the additional splitter 70 and the GDP 20. The plurality of additional pipes 81, 82, 84, 85, and 88 may include a first additional pipe 81, a second additional pipe 82, a fourth additional pipe 84, a fifth additional pipe 85, and an eighth additional pipe 88.

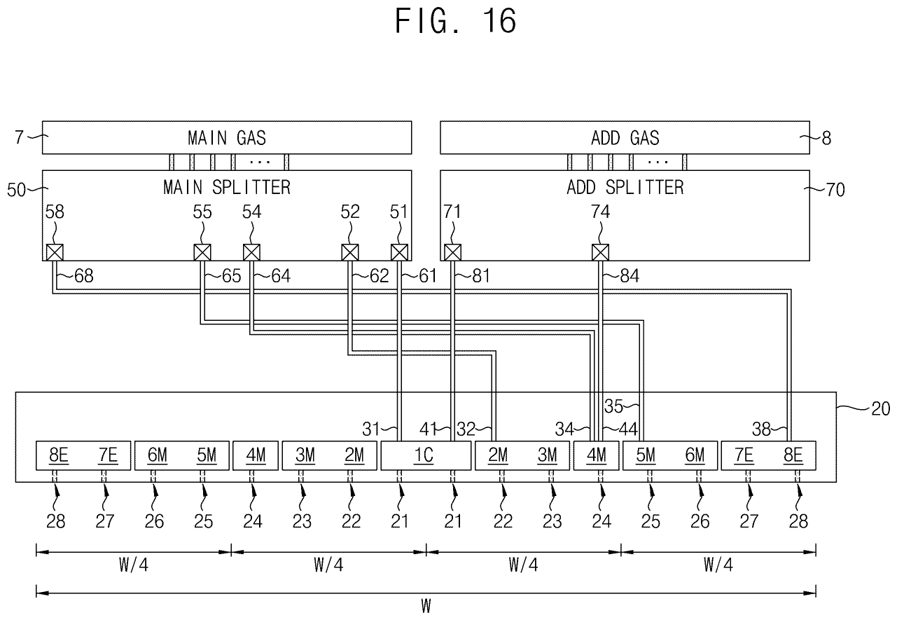

Referring to FIG. 16, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 32, 34, 35, and 38, and a plurality of additional inlet ports 41 and 44. The plurality of additional inlet ports 41 and 44 may include a first additional inlet port 41 and a fourth additional inlet port 44.

The main splitter 50 may include a plurality of main flow controllers 51, 52, 54, 55, and 58. A plurality of main pipes 61, 62, 64, 65, and 68 may be interposed between the main splitter 50 and the GDP 20. An additional splitter 70 may include a plurality of additional flow controllers 71 and 74. The plurality of additional flow controllers 71 and 74 may include a first additional flow controller 71 and a fourth additional flow controller 74. A plurality of additional pipes 81 and 84 may be interposed between the additional splitter 70 and the GDP 20. The plurality of additional pipes 81 and 84 may include a first additional pipe 81 and a fourth additional pipe 84.

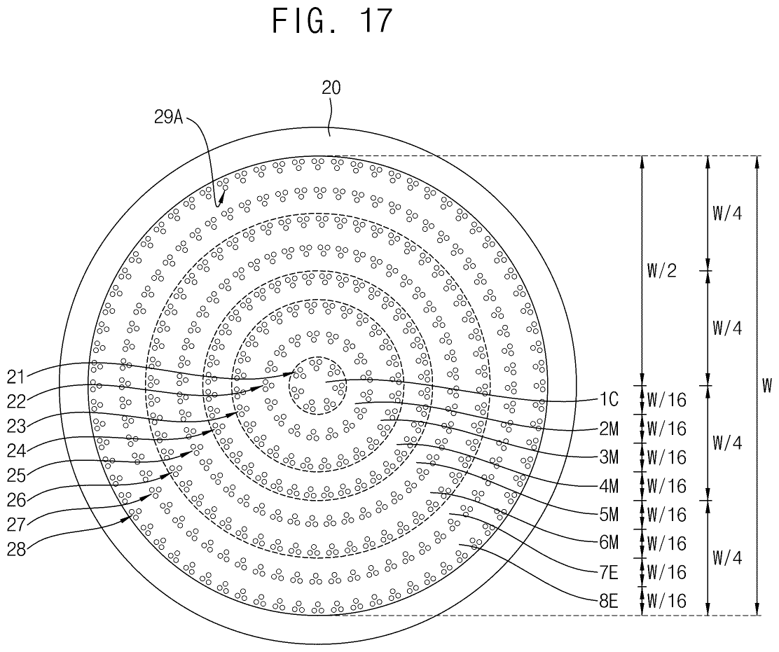

FIG. 17 is a front view illustrating a surface of a GDP used for a plasma processing apparatus according to some embodiments of the inventive concepts.

Referring to FIG. 17, in some embodiments, a third reservoir 3M may be connected to a first reservoir 2M. A fourth reservoir 6M may be connected to a second reservoir 5M. A fifth reservoir 7E may be connected to an outer reservoir 8E.

In some embodiments, the embodiments shown in FIG. 17 may be combined with the embodiments of FIGS. 3 to 6 to be used in various applications.

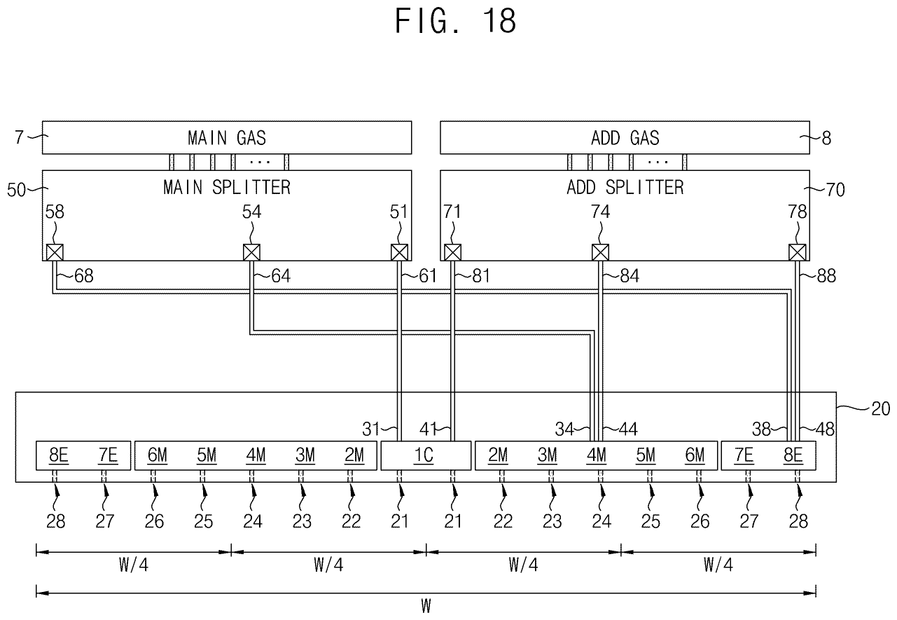

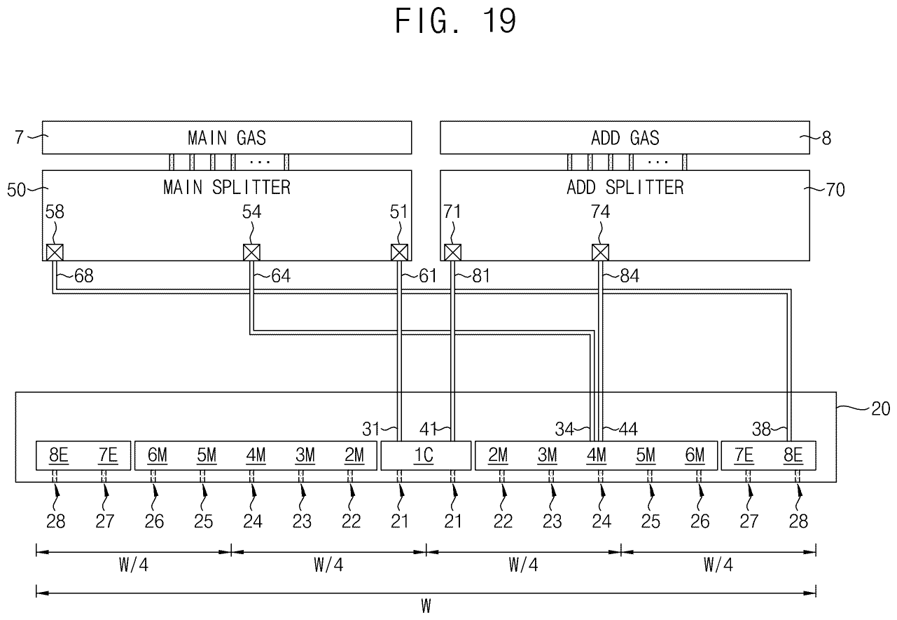

FIGS. 18 and 19 are block diagrams schematically illustrating various examples of a portion of the surface of the GDP of FIG. 1 according to some embodiment of the inventive concepts.

Referring to FIG. 18, in some embodiments, a GDP 20 may include a plurality of reservoirs 1C, 2M, 3M, 4M, 5M, 6M, 7E, and 8E, a plurality of nozzles 21, 22, 23, 24, 25, 26, 27, and 28, a plurality of main inlet ports 31, 34, and 38, and a plurality of additional inlet ports 41, 44, and 48. A first reservoir 2M, a second reservoir 5M, a third reservoir 3M, and a fourth reservoir 6M may be connected to a middle reservoir 4M. A fifth reservoir 7E may be connected to an outer reservoir 8E. The plurality of main inlet ports 31, 34, and 38 may include a first main inlet port 31, a fourth main inlet port 34, and an eighth main inlet port 38. The plurality of additional inlet ports 41, 44, and 48 may include a first additional inlet port 41, a fourth additional inlet port 44, and an eighth additional inlet port 48.

A main splitter 50 may include a plurality of main flow controllers 51, 54, and 58. A plurality of main pipes 61, 64, and 68 may be interposed between the main splitter 50 and the GDP 20. The additional splitter 70 may include a plurality of additional flow controllers 71, 74, and 78. The plurality of additional flow controllers 71, 74, and 78 may include a first additional flow controller 71, a fourth additional flow controller 74, and an eighth additional flow controller 78. A plurality of additional pipes 81, 84, and 88 may be interposed between the additional splitter 70 and the GDP 20. The plurality of additional pipes 81, 84, and 88 may include a first additional pipe 81, a fourth additional pipe 84, and an eighth additional pipe 88.

Referring to FIG. 19, in some embodiments, the additional splitter 70 may include a plurality of additional flow controllers 71 and 74. The plurality of additional flow controllers 71 and 74 may include a first additional flow controller 71 and a fourth additional flow controller 74. A plurality of additional pipes 81 and 84 may be interposed between the additional splitter 70 and the GDP 20. The plurality of additional pipes 81 and 84 may include a first additional pipe 81 and a fourth additional pipe 84.

In some embodiments, the embodiments shown in FIGS. 18 to 19 may be combined with the embodiments of FIGS. 3 to 6 to be used in various applications.

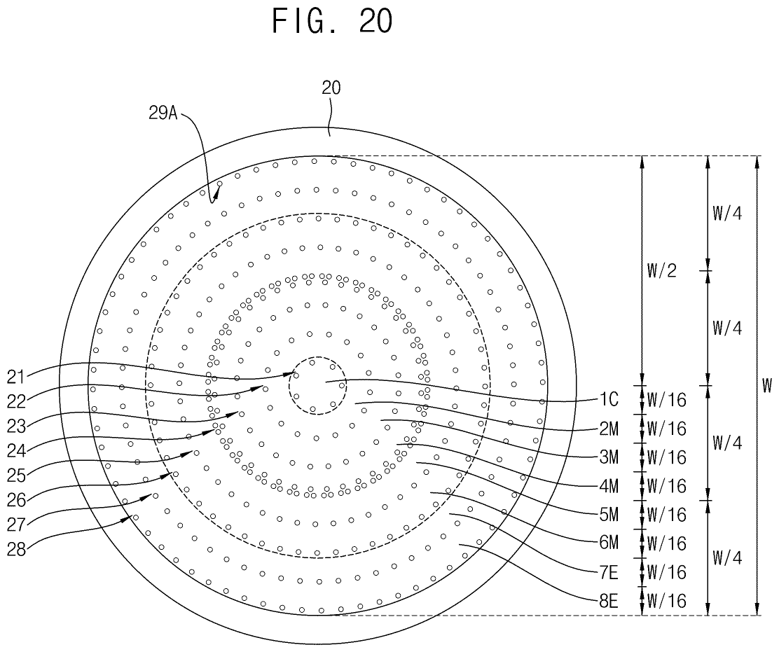

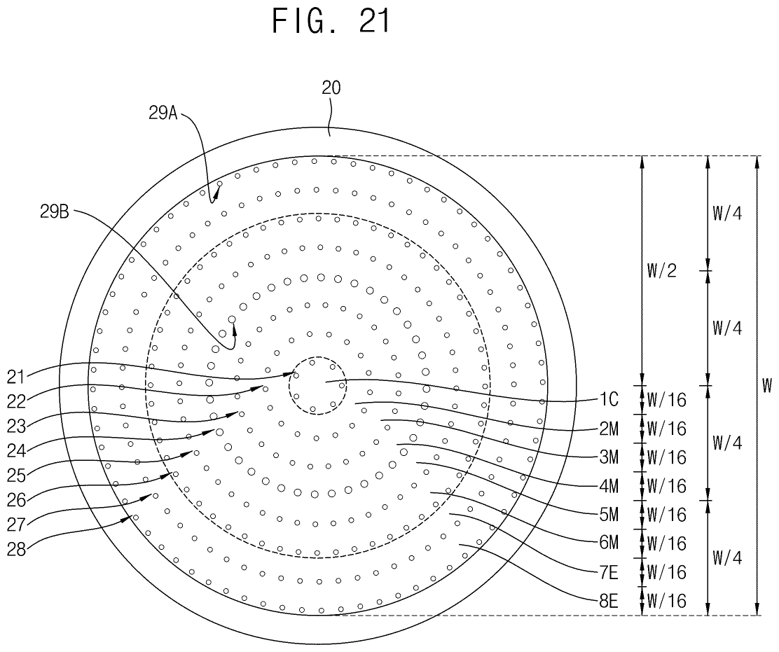

FIGS. 20 and 21 are front views illustrating a surface of a GDP used for a plasma processing apparatus according to some embodiments of the inventive concepts.

Referring to FIG. 20, in some embodiments, a first reservoir 2M, a second reservoir 5M, a third reservoir 3M, and a fourth reservoir 6M may be connected to a middle reservoir 4M. A fifth reservoir 7E may be connected to an outer reservoir 8E. Each of a plurality of middle nozzles 24 may include three first sub-nozzles 29A arranged in a triangular shape. Each of a plurality of central nozzles 21, a plurality of first nozzles 22, a plurality of third nozzles 23, a plurality of second nozzles 25, a plurality of fourth nozzles 26, a plurality of fifth nozzles 27, and a plurality of outer nozzles 28 may include the first sub-nozzle 29A.

Referring to FIG. 21, in some embodiments, a first reservoir 2M, a second reservoir 5M, a third reservoir 3M, and a fourth reservoir 6M may be connected to a middle reservoir 4M. A fifth reservoir 7E may be coupled with an outer reservoir 8E. Each of a plurality of central nozzles 21, a plurality of first nozzles 22, a plurality of third nozzles 23, a plurality of second nozzles 25, a plurality of fourth nozzles 26, a plurality of fifth nozzles 27, and a plurality of outer nozzles 28 may include one first sub-nozzle 29A. Each of the middle nozzles 24 may include one second sub-nozzle 29B. The diameter of the second sub-nozzle 29B may be greater than the diameter of the first sub-nozzle 29A. The ratio of a diameter of the second sub-nozzle 29B to a diameter of the first sub-nozzle 29A may be about 5:3.

According to some embodiments of the inventive concepts, a GDP including a main splitter and an additional splitter may be provided. The additional splitter may be configured to locally provide an acceleration gas for increasing a plasma density of the process gas and/or a deceleration gas for decreasing the plasma density of the process gas. The plasma processing apparatus configured to uniformly control the plasma density can be realized.

While the embodiments of the inventive concepts have been described with reference to the accompanying drawings, it should be understood by those skilled in the art that various modifications may be made without departing from the scope of the inventive concepts and without changing essential features thereof. Therefore, the above-described embodiments should be considered in a descriptive sense only and not for purposes of limitation.

What is claimed is:

1. A plasma processing method, comprising:
a preparing plasma processing apparatus including a main gas supplier, an additional gas supplier, and a chamber,
wherein the chamber comprises:
a support;
a main splitter connected to the main gas supplier;
an additional splitter connected to the additional gas supplier; and
a gas distribution plate (GDP) on the support and connected to the main splitter and the additional splitter,
wherein the GDP comprises reservoirs and nozzles, each connected to a respective reservoir,
wherein the reservoirs comprise:
a first reservoir and a second reservoir connected to the main splitter and not connected to the additional splitter; and
a third reservoir between the first reservoir and the second reservoir and connected to both the main splitter and the additional splitter, and
wherein the first reservoir, the second reservoir, and the third reservoir are separated from each other; and
placing a substrate on the support; and
forming a plasma between the substrate and the GDP using a process gas and an additional gas,
wherein the process gas supplied from the main gas supplier to the chamber is sprayed onto the substrate after passing through the main splitter, the first reservoir, and the second reservoir,
wherein the additional gas supplied from the additional gas supplier to the chamber is sprayed onto the substrate after passing through the additional splitter and the third reservoir, and
wherein the additional gas is an acceleration gas for increasing a plasma density of the process gas or a deceleration gas for decreasing the plasma density of the process gas.

2. The method of claim 1,
wherein the additional gas supplied from the additional gas supplier and sprayed onto the substrate does not pass through the main splitter, the first reservoir, and the second reservoir.

3. The method of claim 1,
wherein the reservoirs further comprise a fourth reservoir connected to the first reservoir, and
wherein the first reservoir is between the fourth reservoir and the third reservoir.

4. The method of claim 3,
wherein the process gas supplied from the main gas supplier to the chamber is sprayed onto the substrate after passing through the main splitter, the first reservoir, the second reservoir, and the fourth reservoir.

5. The method of claim 4,
wherein the additional gas supplied from the additional gas supplier and sprayed onto the substrate does not pass through the main splitter, the first reservoir, the second reservoir, and the fourth reservoir.

6. The method of claim 3,
wherein the reservoirs further comprise a fifth reservoir connected to the second reservoir, and
wherein the second reservoir is between the fifth reservoir and the third reservoir.

7. The method of claim 6,
wherein the process gas supplied from the main gas supplier to the chamber is sprayed onto the substrate after passing through the main splitter, the first reservoir, the second reservoir, the fourth reservoir, and the fifth reservoir.

8. The method of claim 7,
wherein the additional gas supplied from the additional gas supplier and sprayed onto the substrate does not pass through the main splitter, the first reservoir, the second reservoir, the fourth reservoir, and the fifth reservoir.

9. The method of claim 6,
wherein the reservoirs further comprise an outer reservoir,
wherein the fifth reservoir is between the second reservoir and the outer reservoir, and
wherein the outer reservoir is separated from the fifth reservoir.

10. The method of claim 9,
wherein the process gas supplied from the main gas supplier to the chamber is sprayed onto the substrate after passing through the main splitter, the first reservoir, the second reservoir, the fourth reservoir, the fifth reservoir, and the outer reservoir.

11. The method of claim 10,
wherein the additional gas supplied from the additional gas supplier and sprayed onto the substrate does not pass through the main splitter, the first reservoir, the second reservoir, the fourth reservoir, the fifth reservoir, and the outer reservoir.

12. The method of claim 9,
wherein the reservoirs further comprise an outermost reservoir connected to the outer reservoir,
wherein the outer reservoir is between the fifth reservoir and the outermost reservoir.

13. The method of claim 12,
wherein the process gas supplied from the main gas supplier to the chamber is sprayed onto the substrate after passing through the main splitter, the first reservoir, the second reservoir, the fourth reservoir, the fifth reservoir, the outer reservoir, and the outermost reservoir.

14. The method of claim 13,
wherein the additional gas supplied from the additional gas supplier and sprayed onto the substrate does not pass through the main splitter, the first reservoir, the second reservoir, the fourth reservoir, the fifth reservoir, the outer reservoir, and the outermost reservoir.

15. The method of claim 1,
wherein the reservoirs further comprise a central reservoir,
wherein the first reservoir is between the central reservoir and the third reservoir, and
wherein the central reservoir is separated from the first reservoir.

16. The method of claim 15,
wherein the process gas supplied from the main gas supplier to the chamber is sprayed onto the substrate after passing through the main splitter, the first reservoir, the second reservoir, and the central reservoir, and
wherein the additional gas supplied from the additional gas supplier to the chamber is sprayed onto the substrate after passing through the additional splitter, the third reservoir, and the central reservoir.

17. The method of claim 1,
wherein the process gas is different from the additional gas.

18. The method of claim 1,
wherein the acceleration gas comprises Ar, Kr, or Xe.

19. The method of claim 1,
wherein the deceleration gas comprises He or Ne.

20. The method of claim 1,
wherein the nozzles comprise:
a first nozzle connected to the first reservoir;
a second nozzle connected to the second reservoir; and
a third nozzle connected to the third reservoir,
wherein the process gas supplied from the main gas supplier to the chamber is sprayed onto the substrate from the first nozzle, the second nozzle, and the third nozzle, and
wherein the additional gas supplied from the additional gas supplier to the chamber is sprayed onto the substrate from the third nozzle and is not sprayed onto the substrate from the first nozzle and the second nozzle.
